(19) United States
(12) Patent Application Publication
(10) Pub. No.: US 2022/0066112 A1
(43) Pub. Date: Mar. 3, 2022

(54) SERVER AND OPTICAL COMMUNICATION COMPONENT

(71) Applicants: Inventec (Pudong) Technology Corporation, Shanghai (CN); INVENTEC CORPORATION, Taipei (TW)

(72) Inventors: Hsinyu Chen, Taipei (TW); Tai-Jung Sung, Taipei (TW)

(21) Appl. No.: 17/029,473

(22) Filed: Sep. 23, 2020

(30) Foreign Application Priority Data
Sep. 3, 2020 (CN) 202010914801.4

(51) Int. Cl. G02B 6/43; G02B 6/42; H04B 10/25

(52) U.S. Cl. CPC G02B 6/43; H04B 10/25; G02B 6/4214; G02B 6/428

(57) ABSTRACT

A server including chassis and electronic assembly. Chassis including bottom plate, top plate and side plate. Top plate is detachably disposed on side of side plate located away from bottom plate. Bottom plate, top plate, and side plate together form accommodation space. Electronic assembly includes first circuit board, first light-emitting components, second circuit board, first photodetectors and optical communication component. First circuit board is disposed in chassis and located in accommodation space. First light-emitting components are fixed and electrically connected to first circuit board. Second circuit board is disposed in chassis and located in accommodation space. First photodetectors are fixed and electrically connected to second circuit board. Optical communication component includes first substrate and optical fibers. First substrate is fixed to chassis and located in accommodation space. Optical fibers are disposed on first substrate and optically couple first light-emitting components and first photodetectors.

### CROSS-REFERENCE TO RELATED APPLICATIONS

This non-provisional application claims priority under 35 U.S.C. § 119(a) on Patent Application No(s). 202010914801.4 filed in China, on Sep. 3, 2020, the entire contents of which are hereby incorporated by reference.

### BACKGROUND OF THE INVENTION

### Technical Field of the Invention

The invention relates to a server and an optical communication component, more particularly to a server and an optical communication component that include one or more optical fibers.

### Description of the Related Art

A typical server has an electrical cabling system to provide transmission mediums among circuit boards. With the rapid development of electronic technology, the amount of electrical cables required by a server is increased to enable high-speed transmission of large amounts of data.

However, a lot of electrical cables in a very limited internal space of the server usually interfere with the spread of cold air and therefore adversely affect heat dissipation of the server. In addition, electrical cables can become easily tangled together and thus difficult to be installed in the server.

### SUMMARY OF THE INVENTION

The invention is to provide a server and an optical communication component enabling a high-speed transmission of large amounts of data without using a lot of electrical cables.

One embodiment of this invention provides a server including a chassis and an electronic assembly. The chassis including a bottom plate, a top plate and a side plate. The side plate stands on the bottom plate. The top plate is detachably disposed on a side of the side plate that is located away from the bottom plate. The bottom plate, the top plate, and the side plate together form an accommodation space therebetween. The electronic assembly includes a first circuit board, a plurality of first light-emitting components, a second circuit board, a plurality of first photodetectors and an optical communication component. The first circuit board is disposed in the chassis and located in the accommodation space. The plurality of first light-emitting components are fixed and electrically connected to the first circuit board. The second circuit board is disposed in the chassis and located in the accommodation space. The plurality of first photodetectors are fixed and electrically connected to the second circuit board. The optical communication component includes a first substrate and a plurality of optical fibers. The first substrate is fixed to the chassis and located in the accommodation space. The plurality of optical fibers are disposed on the first substrate and optically couple the plurality of first light-emitting components and the plurality of first photodetectors.

Another embodiment of this invention provides an optical communication component configured to optically couple a plurality of light-emitting components and a plurality of photodetectors and including a substrate and a plurality of optical fibers. The substrate is in a form of a flat plate. The plurality of optical fibers are disposed on the substrate and are configured to optically couple the plurality of light-emitting components and the plurality of photodetectors.

According to the server and the optical communication component disclosed by the above embodiments, since the optical fibers are disposed on the first substrate that is fixed to the chassis, all of the fibers can be simultaneously installed in the chassis and optically coupled to the first component and the first photodetector with the help of the first substrate. Therefore, there is no need to install the fibers to the chassis one by one, enabling an easy and convenient installation process of optical fibers. In addition, the optical-fiber cable occupies not too much space in the server so that the usage of the optical-fiber cable does not cause noticeable interfere with the spread of cold air, ensuring the required heat dissipation.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a partially enlarged side cross-sectional view of a server according to one embodiment of the invention;

FIG. 2 is a perspective partially enlarged cross-sectional view of the server in

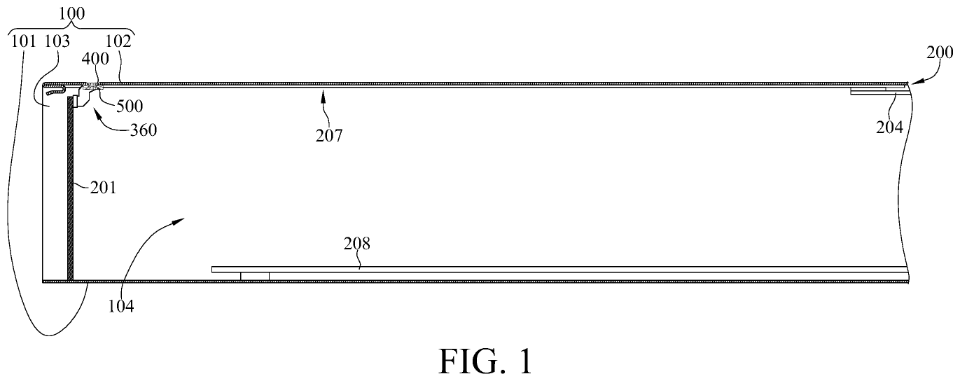

FIG. 1;

FIG. 3 is another perspective partially enlarged cross-sectional view of the server in FIG. 1;

FIG. 4 is another partially enlarged side cross-sectional view of the server in FIG. 1; and

FIG. 5 is a partially enlarged side cross-sectional view of a server according to another embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

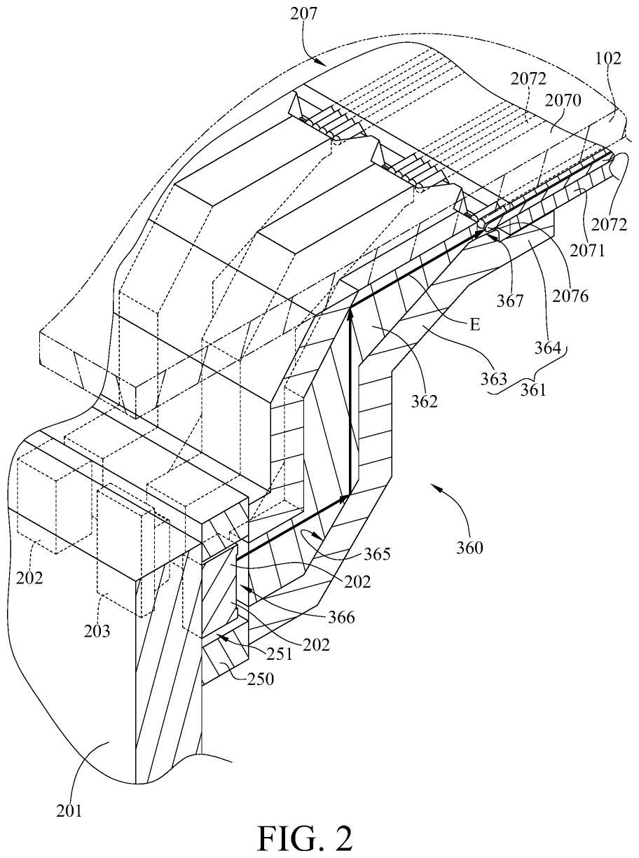

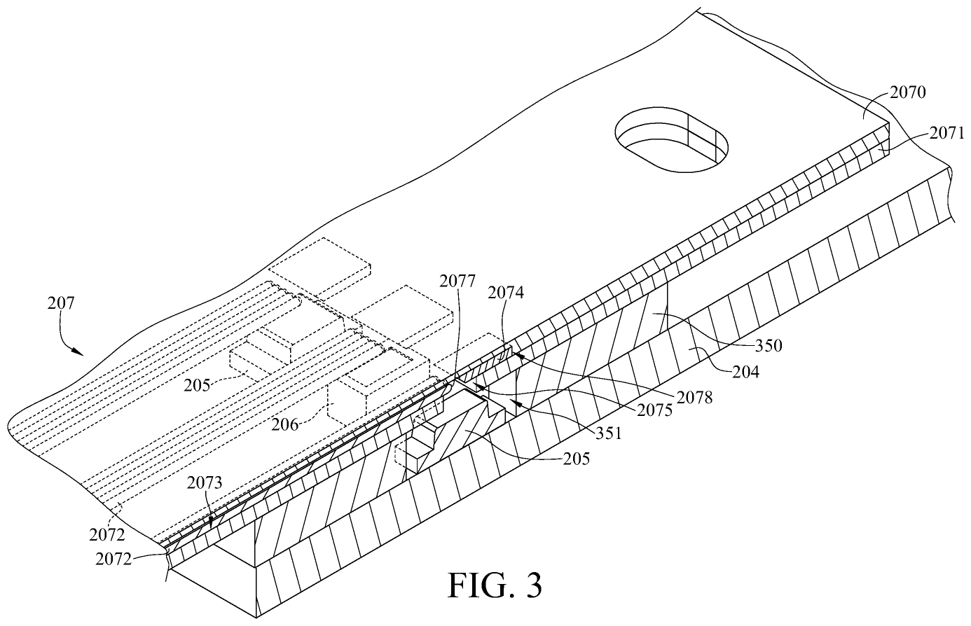

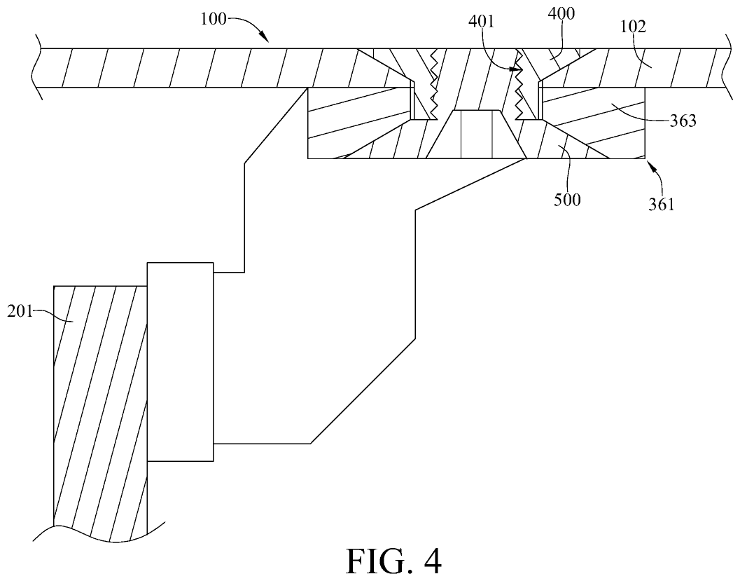

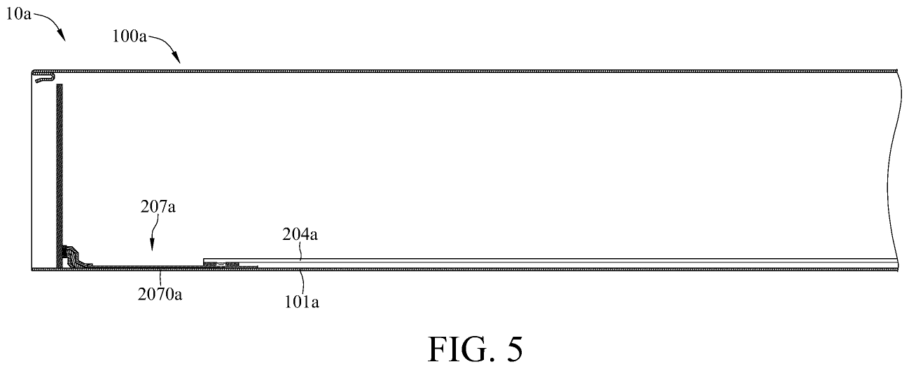

Please refer to FIG. 1 to FIG. 4, where FIG. 1 is a partially enlarged side cross-sectional view of a server 10 according to one embodiment of the invention, FIG. 2 is a partially enlarged perspective cross-sectional view of the server 10 in FIG. 1, FIG. 3 is another partially enlarged perspective cross-sectional view of the server 10 in FIG. 1, and FIG. 4 is another partially enlarged side cross-sectional view of the server 10 in FIG. 1.

In this embodiment, the server 10 includes a chassis 100, an electronic assembly 200, a first cushioning component 250, a second cushioning component 350, a light-guiding structure 360, a positioning pillar 400, and a screw 500. In this embodiment, the chassis 100 includes a bottom plate 101, a top plate 102, and a side plate 103. The side plate 103 stands on the bottom plate 101, and the top plate 102 is detachably disposed on a side of the side plate 103 that is located away from the bottom plate 101. The bottom plate 101, the top plate 102, and the side plate 103 together form an accommodation space 104 therebetween.

In this embodiment, the electronic assembly 200 includes a first circuit board 201, a plurality of first light-emitting components 202, a plurality of second photodetectors 203, a second circuit board 204, a plurality of first photodetectors 205, a plurality of second light-emitting components 206, an optical communication component 207, and a third circuit board 208.

The first circuit board 201 is disposed on the side plate 103 of the chassis 100 and is accommodated in the accommodation space 104, but the invention is not limited thereto. In other embodiments, the first circuit board may be disposed on the bottom plate of the chassis. In addition, the first circuit board 201 is, for example, a disk drive back panel. The first cushioning component 250 is fixed on a side of the first circuit board 201 and includes a plurality of first mounting holes 251 that are spaced apart from one another. Moreover, the first cushioning component 250 is, for example, a synthetic sponge made of soft and porous materials, such as polyester, polyurethane, or vegetal cellulose. In other embodiment, the server may not include the first cushioning component 250.

The first light-emitting components 202 are fixed and electrically connected to the first circuit board 201, and are, for example, light-emitting diodes (LEDs). The second photodetectors 203 are fixed and electrically connected to the first circuit board 201. In addition, the first light-emitting components 202 and the second photodetectors 203 are alternatively accommodated in the first mounting holes 251 of the first cushioning component 250, respectively. That is, any two adjacent first mounting holes 251 respectively accommodate one first light-emitting component 202 and one second photodetector 203.

The second circuit board 204 is disposed on the top plate 102 of the chassis 100 and is accommodated in the accommodation space 104, but the invention is not limited thereto. In other embodiments, the second circuit board may be disposed on the side plate or bottom plate of the chassis. Also, in this embodiment, the second circuit board 204 is arranged, for example, perpendicular to the first circuit board 201, but the invention is not limited thereto. In other embodiments, the second circuit board and the first circuit board may be parallel to each other or the second circuit board may be at an acute angle to the first circuit board. In addition, the second circuit board 204 is, for example, a riser card. The second cushioning component 350 is fixed to a side of the second circuit board 204 and includes a plurality of second mounting holes 351 that are spaced apart from one another. In addition, the second cushioning component 350 is, for example, a synthetic sponge made of soft and porous materials, such as polyester, polyurethane, or vegetal cellulose. In other embodiments, the server may not include the second cushioning component 350.

The first photodetectors 205 are fixed and electrically connected to the second circuit board 204. The second light-emitting components 206 are fixed and electrically connected to the second circuit board 204, and are, for example, LEDs. Moreover, the first photodetectors 205 and the second light-emitting components 206 are alternatively accommodated in the second mounting holes 351 of the second cushioning component 350, respectively. That is, any two adjacent second mounting holes 351 respectively accommodate one first photodetector 205 and one second light-emitting component 206.

In this embodiment, the optical communication component 207 includes a first substrate 2070, a second substrate 2071, a plurality of optical fibers 2072, and a plurality of mirrors 2074. The first substrate 2070 and the second substrate 2071 are in the form of flat plates, and are stacked on each other so as to together form a plurality of first mounting spaces 2073 and a plurality of second mounting spaces 2078. In addition, the second substrate 2071 includes a plurality of through holes 2075. The first mounting spaces 2073 are connected to the second mounting spaces 2078 via the through holes 2075, respectively. The optical fibers 2072 are accommodated in the first mounting spaces 2073, respectively, and each have a first end 2076 and a second end 2077 that are opposite to each other. The mirrors 2074 are accommodated in the second mounting spaces 2078, respectively, and face towards the second ends 2077 of the optical fibers 2072. The first photodetectors 205 and the second light-emitting components 206 are exposed from the through holes 2075, respectively. That is, the second ends 2077 of the optical fibers 2072 are optically coupled to the first photodetectors 205 and the second light-emitting components 206 via the mirrors 2074. In addition, the first substrate 2070 is located between the top plate 102 and the second circuit board 204, and a side of the first substrate 2070 that is located away from the second substrate 2071 is adhered to the top plate 102 of the chassis 100 using any suitable adhesive (e.g., one or more double-sided tapes), but the invention is not limited thereto. In other embodiments, the first substrate may be fixed to the top plate via one or more screws or other suitable fasteners. The second cushioning component 350 is clamped by a side of the second substrate 2071 that is located away from the first substrate 2070 and the second circuit board 204. It is noted that, in this embodiment, the first substrate 2070 and the second substrate 2071 are, for example, polyester films (or may be referred as Mylar sheets), but the invention is not limited thereto. In other embodiment, the first substrate and the second substrate may be made of different materials and the first substrate and the second substrate may be films made of other materials other than polyester.

The third circuit board 208 is disposed on the bottom plate 101 of the chassis 100 and is accommodated in the accommodation space 104. The third circuit board 208 is electrically connected to the second circuit board 204, and is, for example, a motherboard. It is noted that, in other embodiments, the electronic assembly may not include the third circuit board 208.

In this embodiment, the light-guiding structure 360 is manufactured by, for example, double injection molding and includes an opaque part 361 and a plurality of transparent parts 362, where the opaque part 361 is made of, for example, plastic, and the transparent part 362 is made of, for example, Polycarbonate (PC). In this embodiment, the opaque part 361 includes a body 363 and a protruding plate 364. The protruding plate 364 protrudes from the body 363. The first substrate 2070 and the second substrate 2071 of the optical communication component 207 are clamped by the protruding plate 364 and the top plate 102 of the chassis 100. That is, the protruding plate 364 helps position the optical communication component 207 and the top plate 102. The body 363 includes a plurality of accommodation holes 365, a plurality of first apertures 366, and a plurality of second apertures 367. Each first aperture 366 is located on a side of each accommodation hole 365. Each second aperture 367 is located on the other side of each accommodation hole 365. The transparent parts 362 are accommodated in the accommodation holes 365 of the opaque part 361, respectively, and function as a convex lens. A side of each transparent part 362 is exposed from each first aperture 366 so that the first light-emitting components 202 and the second photodetectors 203 are optically coupled to the transparent parts 362, respectively. The other side of each transparent part 362 is exposed from each second aperture 367 so that the transparent parts 362 are optically coupled to the first ends 2076 of the optical fibers 2072 of the optical communication component 207. In other words, the first light-emitting components 202 and the second photodetectors 203 are optically coupled to the first ends 2076 of the optical fibers 2072 via the light-guiding structure 360.

In other embodiments, the opaque part may not include the protruding plate 364 and the optical communication component and the top plate may be fixed in position only by fixing the side of the first substrate that is located away from the second substrate to the top plate.

The positioning pillar 400 is fixed to the top plate 102 of the chassis 100 and the body 363 of the opaque part 361. The positioning pillar 400 includes a screw hole 401. The screw 500 is screwed into the screw hole 401 of the positioning pillar 400 from a side of the body 363 of the opaque part 361 that is located away from the top plate 102, thereby fixing the body 363 of the opaque part 361 and the top plate 102 in position. In other embodiments, the server may not include the position pillar 400 and the screw 500, and the body of the opaque part and the top plate may be riveted to each other.

Specifically, please refer to FIG. 1 to FIG. 3, when the first circuit board 201 controls the first light-emitting component 202 to emit light, the light emitted from the first light-emitting component 202 is transmitted into the transparent part 362 via the first aperture 366 of the body 363 of the opaque part 361 along a light-transmitting direction E. The light transmitted into the transparent part 362 is transmitted into the first end 2076 of the optical fiber 2072 via the second aperture 367 of the body 363 of the opaque part 361 along the light-transmitting direction E. The light transmitted into the optical fiber 2072 is transmitted out of the second end 2077 of the optical fiber 2072 and reflected by the mirror 2074 so that the light passes through the through hole 2075 and is received by the first photodetector 205. As a result, the second circuit board 204 can transmit signals to the third circuit board 208 according to the signals received from the first circuit board 201, such that the first circuit board 201 can transmit signals to the third circuit board 208 via the second circuit board 204.

Similarly, when the third circuit board 208 transmits signals to the second circuit board 204 to force the second circuit board 204 to control the second light-emitting component 206 to emit light, the light emitted from the second light-emitting component 206 passes through the through hole 2075 and is reflected by the mirrors 2074 and thus is transmitted into the second end 2077 of the optical fiber 2072. The light transmitted into the optical fiber 2072 is transmitted out of the first end 2076 of the optical fiber 2072 and is transmitted into the transparent part 362 via the second aperture 367 of the body 363 of the opaque part 361 along a direction that is opposite to the light-transmitting direction E. The light transmitted into the transparent part 362 is transmitted out of the first apertures 366 of the body 363 of the opaque part 361 along the direction that is opposite to the light-transmitting direction E and is received by the second photodetector 203. As a result, the second circuit board 204 is allowed to transmit signals to the first circuit board 201 according to the signals received from the third circuit board 208, such that the third circuit board 208 can transmit signals to the first circuit board 201 via the second circuit board 204.

Briefly speaking, the first light-emitting component 202 and the first photodetector 205 are optically coupled via the optical communication component 207 and the light-guiding structure 360, and the second photodetector 203 and the second light-emitting component 206 are also optically coupled via the optical communication component 207 and the light-guiding structure 360. In addition, in this embodiment, the first substrate 2070 and the second substrate 2071 are in the form of flat plates, such that the optical fibers 2072 can be aligned with the first light-emitting components 202, the first photodetectors 205, the second photodetectors 203 and the second light-emitting components 206 in a convenient manner, and the aforementioned optical coupling is enabled only via the first substrate 2070 and the light-guiding structure 360 that are fixed to the top plate 102 of the chassis 100. However, the invention is not limited by the form of the first substrate 2070 and the second substrate 2071. In other embodiments, as long as being able to help the light-emitting components and photodetectors to be aligned with the optical fiber, the first substrate and the second substrate may be in the form of a ferrule or other suitable forms. In still other embodiments, the sever may not include the light-guiding structure 360 and the optical fibers may be aligned with the light-emitting components and photodetectors only via the first substrate that is fixed to the chassis.

It is noted that, in other embodiments, the electronic assembly may only include one first light-emitting component, one first photodetector, one second light-emitting component and one second photodetector. Alternatively, in still other embodiments, the electronic assembly may only include one first light-emitting component and one first photodetector and may not include the second light-emitting component 206 and the second photodetector 203.

Moreover, in other embodiments, as long as the aforementioned optical coupling is achieved, the optical communication component may not include the second substrate 2071.

The first substrate is not limited to be fixed to the top plate of the chassis. Please refer to FIG. 5 that is a partially enlarged side cross-sectional view of a server according to another embodiment of the invention. In this embodiment, the server 10a does not include the third circuit board in the above embodiments. Also, in this embodiment, a second circuit board 204a is, for example, a motherboard and is disposed on a bottom plate 101a of a chassis 100a. In addition, in this embodiment, a first substrate 2070a is fixed to the bottom plate 101a of the chassis 100a and is located between the bottom plate 101a and the second circuit board 204a. That is, an optical communication component 207a is disposed in a space originally existing between the second circuit board 204a and the bottom plate 101a. As such, the space utilization of the server 10a is improved.

In some embodiments of the invention, the server may be particularly for artificial intelligence (AI) computation, edge computation, or be a 5G server, cloud computing server, or internet of vehicle server.

According to the server and the optical communication component disclosed by the above embodiments, since the optical fibers are disposed on the first substrate that is fixed to the chassis, all of the fibers can be simultaneously installed in the chassis and optically coupled to the first component and the first photodetector with the help of the first substrate. Therefore, there is no need to install the fibers to the chassis one by one, enabling an easy and convenient installation process of optical fibers. In addition, the optical-fiber cable occupies not too much space in the server so that the usage of the optical-fiber cable does not cause noticeable interfere with the spread of cold air, ensuring the required heat dissipation.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A server, comprising:
a chassis, the chassis comprising a bottom plate, a top plate and a side plate, the side plate standing on the bottom plate, the top plate detachably disposed on a side of the side plate that is located away from the bottom plate, and the bottom plate, the top plate, and the side plate together forming an accommodation space therebetween; and
an electronic assembly, comprising:
a first circuit board, the first circuit board disposed in the chassis and located in the accommodation space;
a plurality of first light-emitting components, the plurality of first light-emitting components fixed and electrically connected to the first circuit board;
a second circuit board, the second circuit board disposed in the chassis and located in the accommodation space;
a plurality of first photodetectors, the plurality of first photodetectors fixed and electrically connected to the second circuit board; and
an optical communication component, the optical communication component comprising a first substrate and a plurality of optical fibers, the first substrate fixed to the chassis and located in the accommodation space, and the plurality of optical fibers disposed on the first substrate and optically coupling the plurality of first light-emitting components and the plurality of first photodetectors.

2. The server according to claim 1, wherein the first substrate of the optical communication component is in a form of a flat plate, the plurality of optical fibers of the optical communication component are aligned with the plurality of first light-emitting components and the plurality of first photodetectors only via the first substrate that is fixed to the chassis, and are optically coupled to the plurality of first light-emitting components and the plurality of first photodetectors.

3. The server according to claim 1, wherein, the first circuit board is disposed on the side pate of the chassis, the second circuit board is disposed on the top plate of the chassis, and the first substrate is fixed to the top plate of the chassis and is located between the top plate and the second circuit board.

4. The server according to claim 2, further comprising a light-guiding structure, wherein the light-guiding structure comprises an opaque part and a plurality of transparent parts, the opaque part is fixed to the top plate, the opaque part comprises a plurality of accommodation holes, a plurality of first apertures and a plurality of second apertures, each of the plurality of first apertures is located on a side of each of the plurality of accommodation holes, each of the plurality of second apertures is located on another side of each of the plurality of accommodation holes, the plurality of transparent parts are respectively accommodated in the plurality of accommodation holes of the opaque part, a side of each of the plurality of transparent parts is exposed from each of the plurality of first apertures so that the plurality of transparent parts are optically coupled to the plurality of first light-emitting components, and another side of each of the plurality of transparent parts is exposed from each of the plurality of second apertures so that the plurality of transparent parts is optically coupled to the plurality of optical fibers.

5. The server according to claim 4, further comprising a positioning pillar and a screw, wherein the positioning pillar is fixed in the top plate of the chassis and the opaque part of the light-guiding structure, the positioning pillar comprises a screw hole, and the screw is screwed into the screw hole of the positioning pillar from a side of the opaque part that is located away from the top plate so as to fix the opaque part and the top plate in position.

6. The server according to claim 4, wherein the opaque part comprises a body and a protruding plate, the protruding plate protrudes from the body, the accommodation holes, the plurality of first apertures and the plurality of second apertures are located on the body, the first substrate is clamped by the protruding plate and the top plate.

7. The server according to claim 1, wherein the optical communication component further comprises a second substrate, the first substrate and the second substrate are stacked on each other so as to together form a plurality of accommodation holes, the plurality of optical fibers are respectively accommodated in the plurality of accommodation holes, and a side of the first substrate that is located away from the second substrate is fixed to the chassis.

8. The server according to claim 1, wherein the first circuit board is disposed on the side pate, the second circuit board is disposed on the bottom plate, and the first substrate is fixed to the bottom plate and is located between the bottom plate and the second circuit board.

9. The server according to claim 1, wherein the electronic assembly further comprises a plurality of second photodetectors and a plurality of second light-emitting component, the plurality of second photodetectors are fixed and electrically connected to the first circuit board, the plurality of second light-emitting component are fixed and electrically connected to the second circuit board, and the plurality of optical fibers optically couple the plurality of second photodetectors and the plurality of second light-emitting component.

10. An optical communication component, configured to optically couple a plurality of light-emitting components and a plurality of photodetectors, and the optical communication component comprising:
a substrate, the substrate in a form of a flat plate; and
a plurality of optical fibers, the plurality of optical fibers disposed on the substrate and are configured to optically couple the plurality of light-emitting components and the plurality of photodetectors.
